(19) United States
(12) Patent Application Publication
(10) Pub. No.: US 2002/0025624 A1
(43) Pub. Date: Feb. 28, 2002

(54) Method for manufacturing capacitor for use in semiconductor device

(76) Inventors: Hoon-Jung Oh, Kyoungki-do (KR); Se-Min Lee, Kyoungki-do (KR); Tae-Hyeok Lee, Kyoungki-do (KR); Il-Keoun Han, Kyoungki-do (KR)

Correspondence Address: Pillsbury Madison & Sutro LLP, Intellectual Property Group, East Tower, Ninth Floor, 1100 New York Avenue, N.W., Ninth Floor, Washington, DC, 20005-3918, US

(21) Appl. No.: 09/942,740

(22) Filed: Aug. 31, 2001

(30) Foreign Application Priority Data
Aug. 31, 2000 (KR) 2000-51338

(51) Int. Cl. H01L 21/8242; H01L 21/20

(52) U.S. Cl. 438/239; 438/253; 438/255; 438/396; 438/398

(57) ABSTRACT

A method for manufacturing a capacitor for use in a semiconductor device comprises forming silicon plugs between junction regions and upper conductive structures by depositing an amorphous silicon layer on a semiconductor substrate and into the contact holes formed in an insulating layer using a low pressure chemical vapor deposition (LPCVD) method. The amorphous silicon layer is then crystallized in an inert gas ambient to form a crystallized silicon layer and a portion of the crystallized silicon layer is removed to expose a top surface of the interlayer insulating film and to form the silicon plugs. Upper conductive structures are then formed on the silicon plugs and a metastable polysilicon (MPS) layer is then selectively formed on the exposed surfaces of the conductive structure.

### FIELD OF THE INVENTION

The present invention relates to a semiconductor device; and, more particularly, to a method for manufacturing a capacitor for use in semiconductor devices that uses amorphous silicon to form a silicon plug.

### DESCRIPTION OF THE PRIOR ART

As is well known, semiconductor devices achieve a higher degree of integration mainly by downsizing the components through miniaturization nowadays. However, there is still a demand for downsizing the area of the memory cell, while providing increased transistor and circuit speeds and improved reliability. Such demands for increased density, performance and reliability require formation of extremely fine device features with high precision. To meet the demand, it is necessary to increase a capacitance of a capacitor and improve the gate dielectric film which is used in both DRAM and logic devices. In attempting to meet these requirements, various researchers have been focused on employing high dielectric materials for the capacitor thin films and the gate dielectric films.

Meanwhile, in order to increase the capacitance for the highly integrated devices, there has been proposed a selective metastable polysilicon (SMPS) method in which a polysilicon electrode of the capacitor has rugged surface so that the surface area of the polysilicon electrode and the resulting capacitance are increased. Furthermore, because the semiconductor device is highly integrated, a plug connector is used to provide electrical connection between junction regions and a corresponding word line or bit line and to connect storage electrodes to each other.

In order to prevent deterioration of the junction region, a doped polysilicon is used as the plug in a conventional method for manufacturing a silicon plug. At this time, because the dopant concentration in the doped polysilicon should be minimized, a deposition process is carried out at a low temperature using an amorphous silicon.

Referring to FIG. 1, there is provided a photograph illustrating a conventional method for manufacturing the capacitor structure. In FIG. 1, a bottom electrode 13 is formed on a silicon plug 12 for connecting a junction region to an electrode of the capacitor. Upon the bottom electrode 13, SMPS 14 is formed. And IIF (interlayer insulating film) 11 is formed beneath the bottom electrode 13.

Since the SMPS 14 is formed by crystallizing the amorphous silicon layer in a high vacuum state, MPS (metastable polysilicon) may be formed the other regions of the amorphous silicon layer during crystallization. If the MPS is formed on the silicon plug 11, a bridge between the plugs 12 or a bridge between the plug 12 and the bottom electrode 13 may occur so that the device isolation characteristics are degraded, thereby causing bit failures and decreasing the yield.

### SUMMARY OF THE INVENTION

It is, therefore, an object of the present invention to provide a method for manufacturing a capacitor for use in a semiconductor device using an amorphous silicon to form a silicon plug.

In accordance with one aspect of the present invention, there is provided a method for manufacturing a capacitor for use in a semiconductor device, the method comprising the steps of: a) preparing an active matrix provided with a semiconductor substrate incorporating therein junction regions, an interlayer insulating film (IIF) formed on the semiconductor substrate and contact holes formed over the junction regions; b) forming an amorphous silicon layer the contact holes and over the IIF by using a low pressure chemical vapor deposition (LPCVD) method; c) crystallizing the amorphous silicon layer in an inert gas ambient, thereby forming a crystallized silicon layer; d) polishing the crystallized silicon layer to a top surface of the IIF, thereby forming silicon plugs; e) forming bottom electrodes on the silicon plugs; and f) forming a metastable polysilicon (MPS) with a rugged surface on the surfaces of the bottom electrodes.

### BRIEF DESCRIPTION OF THE DRAWINGS

The above and other objects and features of the present invention will become apparent from the following description of the preferred embodiments given in conjunction with the accompanying drawings, in which:

FIG. 1 is a photograph illustrating a conventional construction of a capacitor;

FIGS. 2A to 2C are cross sectional views illustrating a method for manufacturing a capacitor in accordance with a preferred embodiment of the present invention; and

FIG. 3 is a flow chart setting forth the manufacturing steps for manufacturing a capacitor according to the present invention.

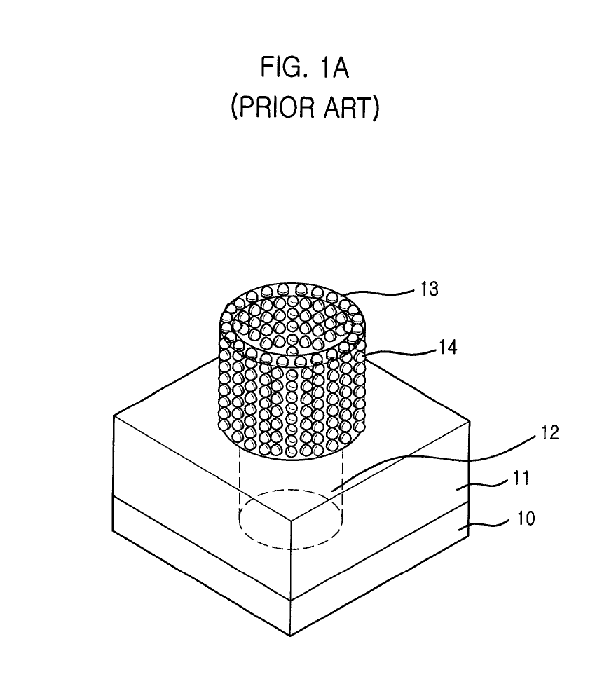

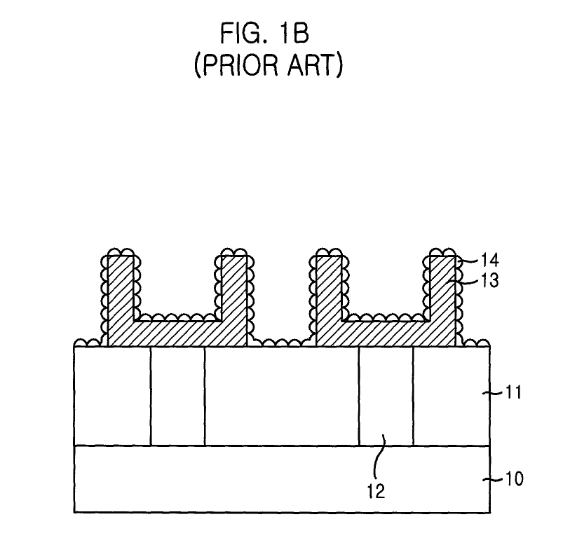

### DETAILED DESCRIPTION OF THE PREFERRED EMBODIMENTS

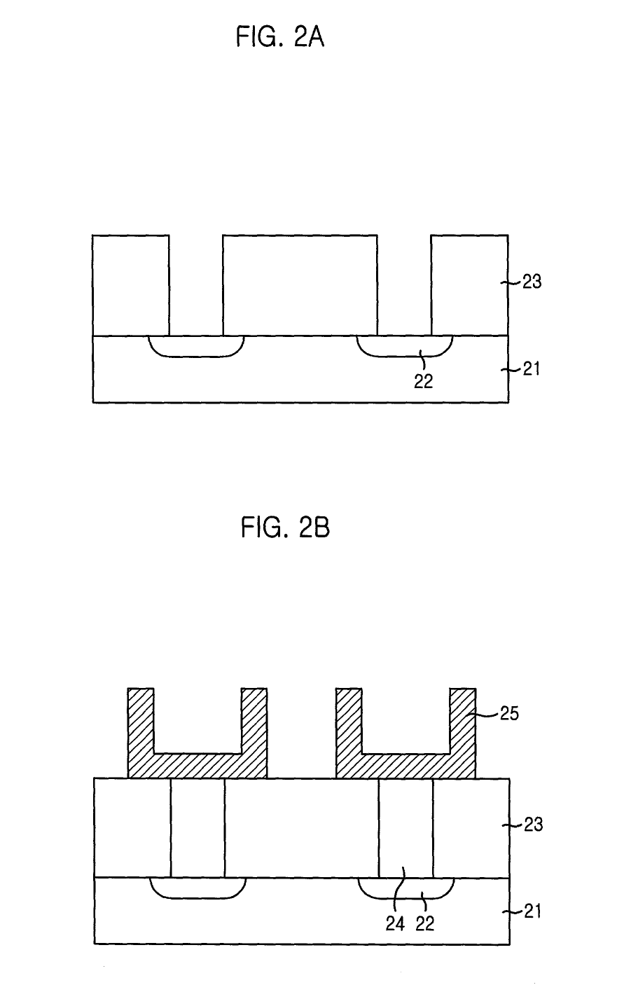

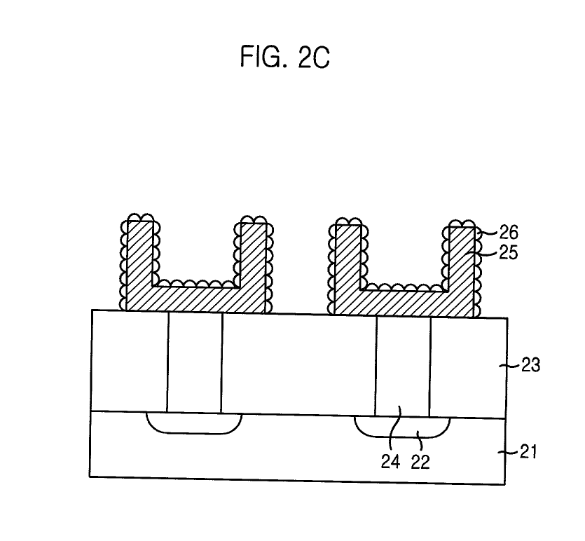

Referring to FIGS. 2A to 2C, there is provided a cross sectional view illustrating the structure of a capacitor manufactured in accordance with a preferred embodiment of the present invention.

As shown in FIG. 2A, the manufacturing steps begin with the preparation of an active matrix provided with a semiconductor substrate 21 incorporating therein junction regions 22, an interlayer insulating film (IIF) 23 and contact holes. The IIF 23 is formed on the semiconductor substrate 21 for isolating capacitors from each other and the IIF 23 is selectively etched to a predetermined configuration, thereby obtaining contact holes. It is preferable that the IIF 23 is made of an insulating material selected from a group consisting of BPSG (borophosphosilicate glass), BSG (borosilicate glass), PSG (phosphosilicate glass), HTO (high temperature oxide), Si₃N₄ or a combination thereof.

Subsequently, as shown in FIG. 2B, silicon plugs 24 are formed in the contact holes and cylindrical bottom electrodes 25 are formed on top of the silicon plugs 24 and the IIF 23.

Thereafter, as shown in FIG. 2B, metastable polysilicons (MPSs) 26 having rugged surfaces thereof are formed on surfaces of the bottom electrodes 25

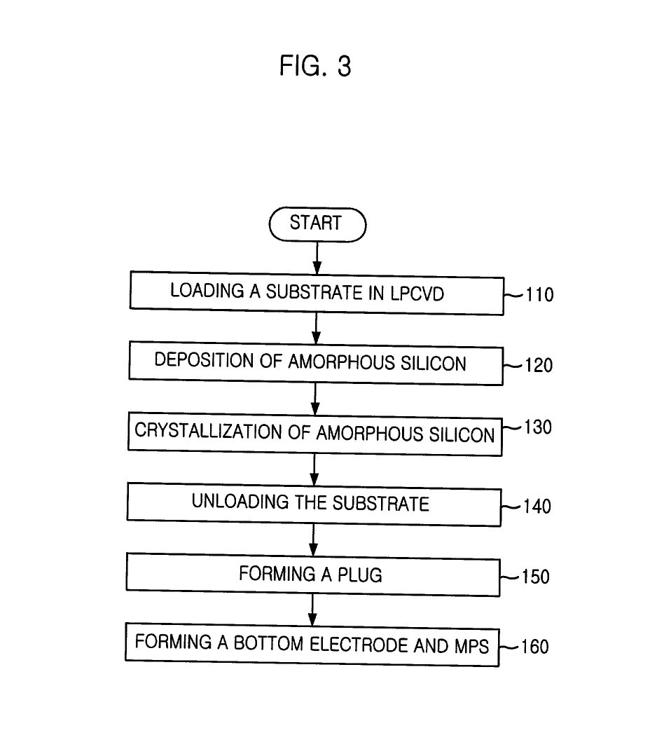

Referring to FIG. 3, there is provided a flow chart setting forth a manufacturing steps for fabricating the capacitor structure of the present invention.

To begin with, a first step 110 is carried out. That is, an active matrix provided with the semiconductor substrate 21, the IIF 23 and the contact holes is loaded into a chamber of a low pressure chemical vapor deposition (LPCVD) apparatus.

In a second step 120, an amorphous silicon is deposited on the semiconductor substrate 21 for forming the silicon plugs 24, whereby the contact holes are filled with the amorphous silicon. At this time, the deposition process is preferably carried out at approximately 560° C.

In a third step 130, a crystallization of the deposited amorphous silicon is performed at a temperature ranging from approximately 580° C. to approximately 650° C. for at least 10 minutes in nitrogen (N₂) or helium (He) gas ambient while the pressure in the chamber increases for unloading the semiconductor substrate 21. The third step for obtaining a crystallized silicon may be carried out in the chamber which the deposition process is carried out or may be carried out in a separate chamber after the deposition step.

In a fourth step 140, the semiconductor substrate 21 on which the crystallized silicon has been formed is unloaded from the chamber of the LPCVD apparatus.

In a fifth step 150, the majority of the crystallized silicon is removed to expose a top surface of the IIF 23 using a method such as an etch-back or a chemical mechanical polishing (CMP) process, thereby obtaining the silicon plug 24.

Finally, a sixth step 160 is carried out to form the bottom electrode 25 on the silicon plug 24 and form the MPS 26 on the surface of the bottom electrode.

In more detail, after formation of the bottom electrode 25, a precleaning process is performed to remove any oxide film on the surface of the bottom electrode 25. Thereafter, silicon seeds are formed on the surface of the bottom electrode 25 under conditions that SiH₄, Si₂H₆ or DCS (SiH₂Cl₂) gas is supplied at a temperature ranging from approximately 550° C. to approximately 670° C. and the pressure ranging from approximately 1 Torr to approximately 7 Torr. After forming the silicon seeds, an annealing process is carried out in order to form the MPS on the surfaces of the bottom electrode.

In comparison with a prior art, the inventive method uses an amorphous silicon in place of a conventional doped polysilicon with the amorphous silicon being crystallized at a temperature below 650° C. for forming the polysilicon plug. Therefore, it is possible to prevent the formation of the MPS on top of the plug, thereby suppressing leakage current and enhancing drivability of the semiconductor device.

While the present invention has been described with respect to the particular embodiments, it will be apparent to those skilled in the art that various changes and modifications may be made without departing from the scope of the invention as defined in the following claims.

What is claimed is:

1. A method for manufacturing a capacitor for use in a semiconductor device, the method comprising the steps of:
a) preparing an active matrix, the active matrix comprising a semiconductor substrate incorporating therein a junction region, an insulating layer formed on the semiconductor substrate and a contact hole formed through the insulating layer to expose a portion of the junction region;
b) forming an amorphous silicon layer on the active matrix in a deposition chamber, the amorphous silicon layer filling the contact hole and extending over the insulating layer;
c) crystallizing the amorphous silicon layer to form a crystallized silicon layer;
d) removing a portion of the crystallized silicon layer to expose a top surface of the insulating layer and to form a silicon plug filling the contact hole;
e) forming a bottom electrode having exposed surfaces, the bottom electrode being in contact with a top surface of the silicon plug; and
f) forming a metastable polysilicon (MPS) on the exposed surfaces of the bottom electrode, the metastable polysilicon having a rugged surface.

2. A method for manufacturing a capacitor for use in a semiconductor device according to claim 1, wherein the step of crystallizing the amorphous silicon is carried out in a nitrogen gas (N₂) ambient.

3. A method for manufacturing a capacitor for use in a semiconductor device according to claim 1, wherein the step step of crystallizing the amorphous silicon is carried out in a helium (He) gas ambient.

4. A method for manufacturing a capacitor for use in a semiconductor device according to claim 1, wherein the step step of crystallizing the amorphous silicon is carried out at a temperature ranging from approximately 580° C. to approximately 650° C.

5. A method for manufacturing a capacitor for use in a semiconductor device according to claim 1, wherein the step of forming the amorphous silicon layer is performed in a chamber and further wherein the subsequent step of crystallizing the amorphous silicon is carried out in the chamber.

6. A method for manufacturing a capacitor for use in a semiconductor device according to claim 1, wherein the step of forming the amorphous silicon layer is carried out in a first chamber and further wherein the step of crystallizing the amorphous silicon is carried out in a second chamber.

7. A method for manufacturing a capacitor for use in a semiconductor device according to claim 1, wherein the insulating layer comprises at least one insulating material selected from a group consisting of BPSG (borophosphosilicate glass), BSG (borosilicate glass), PSG (phosphosilicate glass), HTO (high temperature oxide), and Si₃N₄.

8. A method for manufacturing a capacitor for use in a semiconductor device according to claim 1, wherein the step of removing a portion of the crystallized silicon layer to expose a top surface of the insulating layer utilizes an etch-back process or a chemical mechanical polishing (CMP) process.

9. A method for manufacturing a capacitor for use in a semiconductor device according to claim 1, wherein the step of forming a metastable polysilicon (MPS) on the exposed surfaces of the bottom electrode comprises the steps of:
f1) forming a layer of silicon seeds on the surfaces of the bottom electrode, the silicon seeds being formed at a temperature between about 550° C. and about 670° C., at a pressure between about 1 Torr to about 7 Torr, using at least one gas selected from the group consisting of SiH₄, Si₂H₆ and SiH₂Cl₂; and
f2) annealing the bottom electrode after forming the layer of silicon seeds.

10. A method for forming an interlevel plug connector comprising the steps of:
a) forming an interlayer insulating film on a substrate;
b) patterning and etching the interlayer insulating film to form an etched interlayer insulating film having a plurality of contact holes;
c) depositing an amorphous silicon layer on the etched interlayer insulating film, the amorphous silicon layer filling the contact holes;
d) crystallizing the amorphous silicon layer to form a crystallized silicon layer;
e) removing a portion of the crystallized silicon layer to expose a top surface of the insulating layer and to form silicon plugs filling each of the contact holes;
f) depositing a conductive layer;
g) patterning and etching the conductive layer to form a plurality of conductive structures having exposed surfaces, each conductive structure being in electrical contact with a least one silicon plug; and
h) forming a metastable polysilicon (MPS) on the exposed surfaces of the conductive structure, the metastable polysilicon having a rugged surface.
